(19) United States
(12) Patent Application Publication
(10) Pub. No.: US 2020/0006040 A1
(43) Pub. Date: Jan. 2, 2020

(54) DRY ETCHING DEVICE AND ELECTRODE THEREOF

(71) Applicants: HKC CORPORATION LIMITED, Shenzhen City, Guangdong (CN); CHONGQING HKC OPTOELECTRONICS TECHNOLOGY CORPORATION LIMITED, Chongqing (CN)

(72) Inventor: Chun-Bin WEN, Chongqing (CN)

(73) Assignees: HKC CorporationLimited, Shenzhen City, Guangdong (CN); Chongqing HKC Optoelectronics Technology Corporation Limited, Chongqing (CN)

(21) Appl. No.: 15/541,011

(22) PCT Filed: May 19, 2017
(86) PCT No.: PCT/CN2017/085154

§ 371 Date: Nov. 8, 2018

(30) Foreign Application Priority Data
May 2, 2017 (CN) 201710302181.7

(51) Int. Cl. H01J 37/32

(52) U.S. Cl. CPC H01J 37/32449; H01J 2237/334; H01J 37/32532

(57) ABSTRACT

A dry etching device and an electrode thereof are disclosed in this application. The electrode of a dry etching device includes: an electrode plate, a surface of the electrode plate including a component-disposing area and an edge area surrounding the component-disposing area; a barrier ring, disposed in the edge area, and located on a periphery of the component-disposing area; and spacers, disposed on an outer side of the electrode plate, and abutting a periphery of the barrier ring, where the spacer has a plurality of through holes.

### BACKGROUND

### Technical Field

This application relates to a dry etching device and an electrode of a dry etching device.

### Related Art

With the development of science and technologies, liquid crystal displays (LCDs) become increasingly widespread for the reason of multiple advantages. For example, LCDs are energy saving and free of radiation and have small volumes, low power consumption, flat surfaces, right angles, high resolution, and stable picture quality. Especially, a variety of information products such as mobile phones, notebook computers, digital cameras, PDAs, and liquid crystal screens become increasingly widespread nowadays. As a result, the demands for LCDs are greatly increased. Therefore, the industry of LCD panels develops rapidly, and the production of panels keeps increasing. An etching process is a very important step in a process of manufacturing an array substrate of an LCD panel. According to a physical state of an etchant, the etching process is classified into a dry etching process and a wet etching process. That is, the dry etching process is a process of performing etching by using an etching gas, and the wet etching process is a process of performing etching by using an etching liquid.

In the process of manufacturing an array substrate by using the dry etching process, in an ideal state, under the effect of factors such as a blowing force of a gas intake system, a sucking force of a gas extraction system, and a voltage between electrode plates, an etching gas is blown to the surface of a to-be-processed substrate in a direction completely perpendicular to the surface of the to-be-processed substrate. In an entire manufacturing process, in a precondition of ensuring stable pressure and a stable flow of the etching gas, each part of the surface of the to-be-processed substrate is exposed to an equal amount of etching gas in the entire manufacturing process, so that parts of the to-be-processed substrate are processed at a same rate, thereby ensuring processing uniformity of the parts of the to-be-processed substrate in the manufacturing process.

However, usually a separating mesh or no component is disposed at a corner inside a chamber. In addition, there are factors such as an interior design structure of an etching chamber and a design of a gas extraction system. As a result, in actual operations, an etching gas flows to corners inside a chamber, and etching degrees of four corners are different from an etching degree of another position, causing an improper loading effect. Parts of a to-be-processed substrate have different etching degrees, resulting in undesirable processing uniformity of the parts of the to-be-processed substrate, and consequently, a product becomes a reject.

### SUMMARY

To resolve the foregoing technical problem, an objective of this application is to provide a dry etching device and an electrode thereof, so as to improve distribution uniformity of flow directions of an etching gas without radically changing an existing dry etching procedure.

The objective of this application is achieved and a technical problem of this application is resolved by using the following technical solution: According to this application, an electrode of a dry etching device is provided, where the electrode of a dry etching device comprises: an electrode plate, a surface of the electrode plate comprising a component-disposing area and an edge area surrounding the component-disposing area; a barrier ring, disposed in the edge area, and located on a periphery of the component-disposing area; and spacers, disposed on an outer side of the electrode plate, and abutting a periphery of the barrier ring, where the spacer has a plurality of through holes.

The technical problem of this application may be further resolved in this application by using the following technical solutions:

In an embodiment of this application, the spacers are disposed on the periphery of the barrier ring in a manner of equal intervals, unequal intervals, partially equal intervals or no interval.

In an embodiment of this application, the plurality of through holes is evenly, unevenly, or partially evenly provided on the spacer.

In an embodiment of this application, the plurality of through holes has a same shape and size, different shapes and sizes, or partially same shapes and sizes.

Another objective of this application is to provide a dry etching apparatus, comprising: a chamber; a base, disposed inside the chamber; a first electrode, disposed on the base, and a surface of the first electrode comprising a component-disposing area and an edge area surrounding the component-disposing area; a barrier ring, disposed in the edge area, and located on a periphery of the component-disposing area; spacers, disposed on an outer edge of the first electrode, and located on a periphery of the barrier ring, where the spacer has a plurality of through holes; a second electrode, disposed inside the chamber, and disposed opposite to the first electrode; a gas inlet, disposed on an inner side of the chamber, where a horizontal position of the gas inlet is higher than a horizontal position of the first electrode; and a gas extraction opening, disposed on the inner side of the chamber, where a horizontal position of the gas extraction opening is lower than the horizontal position of the first electrode.

The technical problem of this application may be further resolved in this application by using the following technical solutions:

In an embodiment of this application, the spacers are disposed on the periphery of the barrier ring in a manner of equal intervals, unequal intervals, partially equal intervals or no interval.

In an embodiment of this application, the plurality of through holes is evenly, unevenly, or partially evenly provided on the spacer.

In an embodiment of this application, the plurality of through holes has a same shape and size, different shapes and sizes, or partially same shapes and sizes.

In an embodiment of this application, the gas extraction opening is disposed at a bottom of the chamber, and is disposed opposite to an opening of the spacer.

In an embodiment of this application, the gas extraction opening is disposed on a side of the chamber, and abuts an opening of the spacer.

Still another objective of this application is to provide a dry etching apparatus, comprising: a chamber; a base, disposed inside the chamber; a first electrode, disposed on the base, and a surface of the first electrode comprising a component-disposing area and an edge area surrounding the component-disposing area; a barrier ring, disposed in the edge area, and located on a periphery of the component-disposing area; spacers, disposed on an outer side of an electrode plate, and abutting a periphery of the barrier ring, where the spacer has a plurality of through holes; a second electrode, disposed inside the chamber, and disposed opposite to the first electrode; a gas inlet, disposed on an inner side of the chamber, where a horizontal position of the gas inlet is higher than a horizontal position of the first electrode; and a gas extraction opening, disposed on the inner side of the chamber, where a horizontal position of the gas extraction opening is lower than the horizontal position of the first electrode, where the spacers are disposed on the periphery of the barrier ring in a manner of equal intervals, unequal intervals, partially equal intervals or no interval; the plurality of through holes is evenly, unevenly, or partially evenly provided on the spacer; the plurality of through holes has a same shape and size, different shapes and sizes, or partially same shapes and sizes; and the plurality of through holes is used to restrict a flow rate, a flow direction, and gas distribution uniformity of an etching gas.

By means of this application, distribution uniformity of flow directions of an etching gas may be improved without radically changing an existing dry etching procedure. The etching gas is prevented from constantly flowing to corners inside a chamber. Differences between etching degrees of four corners and an etching degree of another position of a to-be-processed substrate are reduced. An improper loading effect is reduced. Processing uniformity of parts of the to-be-processed substrate is maintained. The manufacturing yield of the to-be-processed substrate is increased.

### BRIEF DESCRIPTION OF THE DRAWINGS

FIG. 1a is a schematic structural diagram of a dry etching device serving as an example;

FIG. 1b is a schematic structural top view of an electrode of a dry etching device serving as an example;

FIG. 2 is a schematic structural top view showing that an embodiment is applied to an electrode of a dry etching device according to a method of this application;

FIG. 3 is a schematic structural cross-sectional view showing that an embodiment is applied to a dry etching device according to a method of this application;

FIG. 4 is a schematic structural top view showing that an embodiment is applied to an electrode of a dry etching device according to a method of this application;

FIG. 5 is a schematic structural top view showing that an embodiment is applied to an electrode of a dry etching device according to a method of this application; and

FIG. 6 is a schematic structural top view showing that an embodiment is applied to an electrode of a dry etching device according to a method of this application.

### DETAILED DESCRIPTION

The following embodiments are described with reference to the accompanying drawings, which are used to exemplify specific embodiments for implementation of this application. Terms about directions mentioned in this application, such as “on”, “below”, “front”, “back”, “left”, “right”, “in”, “out”, and “side surface” merely refer to directions of the accompanying drawings. Therefore, the used terms about directions are used to describe and understand this application, and are not intended to limit this application.

The accompanying drawings and the description are considered to be essentially exemplary, rather than limitative. In figures, units with similar structures are represented by using a same reference number. In addition, for understanding and ease of description, a size and a thickness of each component shown in the accompanying drawings are arbitrarily shown, but this application is not limited thereto.

In the accompanying drawings, for clarity, thicknesses of a layer, a film, a panel, an area, and the like are enlarged. In the accompanying drawings, for understanding and ease of description, thicknesses of some layers and areas are enlarged. It should be understood that when a component such as a layer, a film, an area, or a substrate is described to be “on” “another component”, the component may be directly on the another component, or there may be an intermediate component.

In addition, in this specification, unless otherwise explicitly described to have an opposite meaning, the word “include” is understood as including the component, but not excluding any other component. In addition, in this specification, “on” means that a component is located on or below a target component, but does not mean that the component needs to be located on top of a gravity direction.

To further describe the technical means adopted in this application to achieve the present application objective and effects thereof, specific implementations, structures, features, and effects of a dry etching device and an electrode of a dry etching device, to which the structure is applied that are provided in this application are described in detail below with reference to the accompanying drawings and preferred embodiments.

In a process of manufacturing an integrated circuit of an electronic device, an entire circuit pattern usually needs to be defined on a surface of a workpiece. A procedure of manufacturing the integrated circuit usually includes: first, covering a to-be-processed surface of a to-be-processed workpiece with a film; then, defining the circuit pattern on the film using a photoresist by using a lithography technique; and subsequently, removing an unwanted part in a chemical or physical manner. Such a removal step is referred to as etching. In an etching process, an overall etching degree of a workpiece in a process is usually described by using process uniformity. In a particular process, when etching degrees of different positions on a processing surface of a workpiece are closer to each other, the process uniformity of the workpiece is higher. To ensure that etching processing on parts of a workpiece to be completed at the same time and to ensure the processing yield of the workpiece and the quality of the workpiece, etching degrees of the parts of the workpiece need to be controlled to ensure that the parts of the to-be-processed workpiece can be etched at a same rate, that is, to ensure relatively high process uniformity in the etching process.

The etching process is generally classified into a wet etching process and a dry etching process. As the names imply, the wet etching process is performing etching by using a liquid as a medium, and the dry etching process is performing etching by using a gas as a medium. Therefore, for the dry etching process, in an entire process, an amount of an etching gas to which a to-be-processed surface of a to-be-processed workpiece is exposed is a key factor for determining an etching rate. Process uniformity of the dry etching device is generally improved by adjusting parameters such as a pressure and a gas flow. However, with an increasing requirement for process uniformity, it is very difficult to further improve the process uniformity only by adjusting the foregoing parameters. Especially, currently to-be-processed workpieces have increasingly large sizes, and it is increasingly difficult to improve the process uniformity.

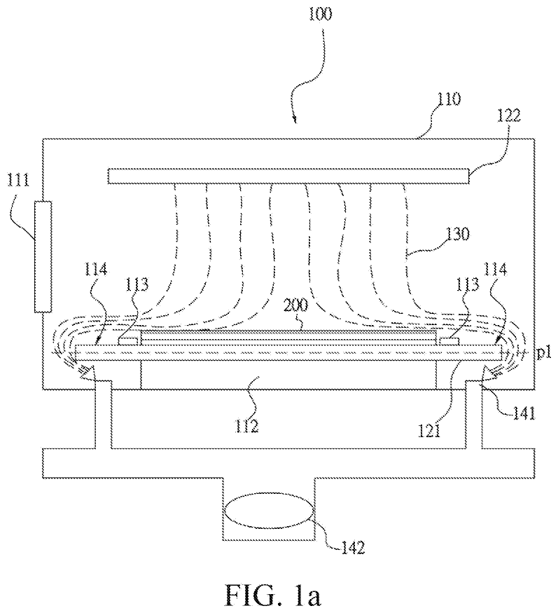

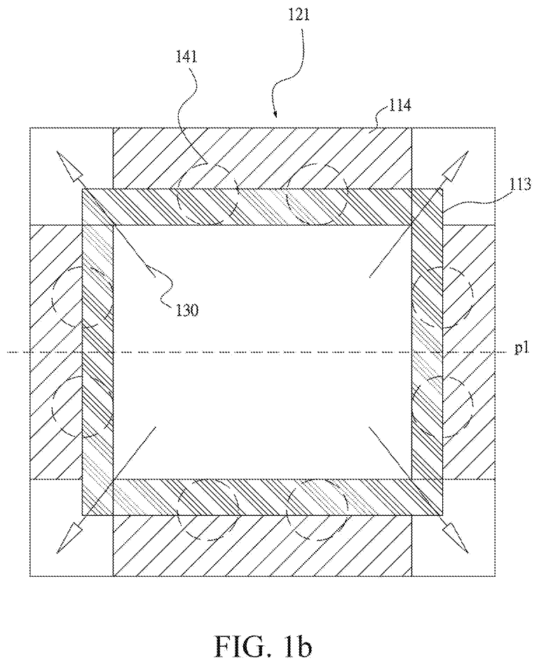

FIG. 1a is a schematic structural diagram of a dry etching device serving as an example. FIG. 1b is a schematic structural top view of an electrode of the dry etching device serving as an example. As shown in FIG. 1a, the dry etching device 100 includes a chamber 110 for a to-be-processed substrate 200 to perform etching. A chamber door 111 used to convey the to-be-processed substrate 200 is disposed on a side of the chamber 110. A base 112 is disposed inside the chamber 110. The base 112 is usually disposed at a bottom of the chamber 110. The base 112 is used to place the to-be-processed substrate 200. A first electrode 121 and a second electrode 122 are disposed opposite to each other inside the chamber 110, and are used to control a flow direction of an etching gas 130. One of the first electrode 121 and the second electrode 122 is usually disposed above the chamber 110, and the other of the first electrode 121 and the second electrode 122 is usually disposed on the base 112 at the bottom of the chamber 110. A gas extraction opening 141 is provided at the bottom or on a side of the chamber 110 of the dry etching device 100, and is disposed fitting a gas discharge apparatus 142 to discharge the etching gas 130. In some embodiments, the gas discharge apparatus 142 may be directly disposed in the position of the gas extraction opening 141. In principle, a horizontal position of the gas extraction opening 141 needs to be lower than a horizontal position of the first electrode 121. A gas inlet is disposed at a top or on a side of the chamber 110 of the dry etching device 100, and is disposed fitting a gas intake apparatus to blow in the etching gas 130. In some embodiments, the gas intake apparatus may be directly disposed in the position of the gas inlet. In principle, a horizontal position of the gas inlet needs to be higher than the horizontal position of the first electrode 121. In some embodiments, a gas intake system of the dry etching device 100 is built at the second electrode 122 at the top of the etching chamber 110, and is used to blow in the etching gas 130. Because the position of the gas inlet overlaps that of the second electrode 122, the gas inlet is not specifically shown in FIG. 1a.

Still referring to FIG. 1a and FIG. 1b, a barrier ring 113 is disposed on a surface of the first electrode 121. The barrier ring 113 provides functions of slide prevention, component stabilization, and fixation when the to-be-processed substrate 200 is placed on the first electrode 121. Spacers 114 are disposed on an outermost side of the first electrode 121, in principle, an outer edge of the barrier ring 113. The spacer 114 is used to block the etching gas 130 to effectively control a flow rate and a flow direction of the etching gas 130 and deliberately protect a part of the first electrode 121. However, the spacer 114 generally has a flat design. To prevent the etching gas 130 from staying on the to-be-processed substrate 200, corners inside the chamber 110 are generally designed to be empty, that is, no component is disposed; or a separating mesh is disposed according to a requirement of a designer.

The electrode of a dry etching device is optimized and improved in this application, thereby improving a flow direction of an etching gas in a manufacturing process, achieving an objective of controlling an amount of the etching gas to which different positions on a to-be-processed surface of a to-be-processed workpiece are exposed in an entire process, and improving process uniformity.

The process uniformity can be improved by using the dry etching device 100 of this application. Herein, an operating manner of this application is mainly described based on the dry etching device 100 that processes an LCD panel. Next, the etching process mainly involves processing of a glass substrate. However, it should be noted that application of the dry etching device 100 in this application is not limited thereto. For any processing and manufacturing procedure using the dry etching processing process, the dry etching device 100 described in this application may be used.

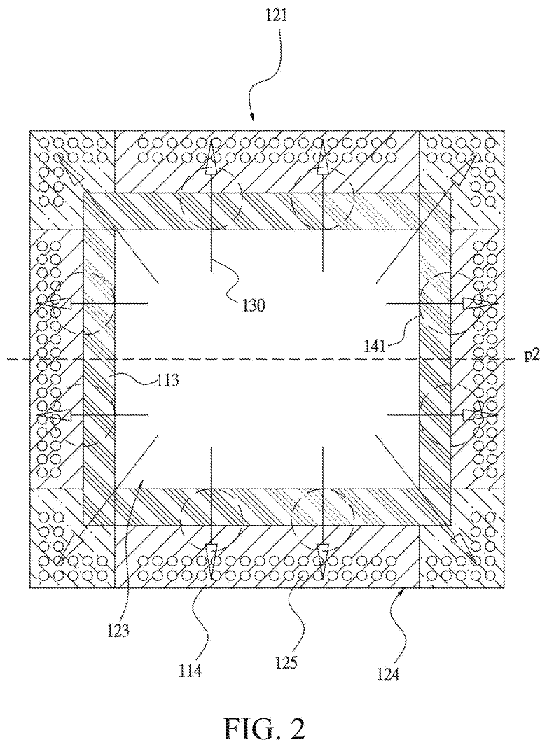

FIG. 2 is a schematic structural top view showing that an embodiment is applied to an electrode of a dry etching device according to a method of this application. Referring to FIG. 2, in an embodiment of this application, an electrode of a dry etching device 100 includes: an electrode plate (using the first electrode 121 as an example), a surface of the electrode plate including a component-disposing area 123 and an edge area 124 surrounding the component-disposing area 123; a barrier ring 113, disposed in the edge area 124, and located on a periphery of the component-disposing area 123; and spacers 114, disposed on an outer edge of the first electrode 121, and located on a periphery of the barrier ring 113, where the spacer 114 has a plurality of through holes.

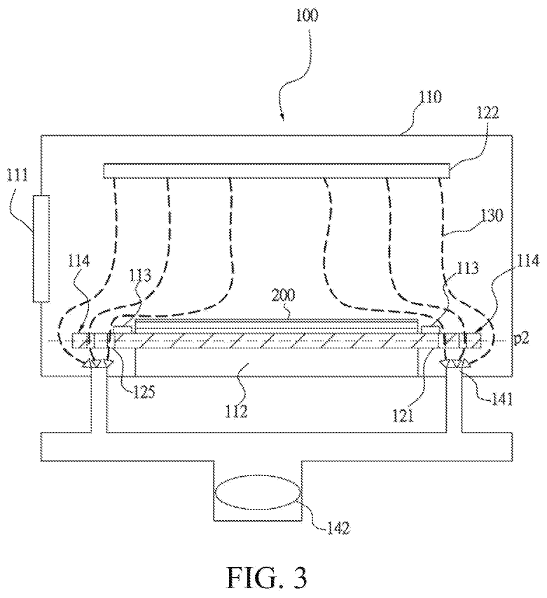

FIG. 3 is a schematic structural cross-sectional view showing that an embodiment is applied to a dry etching device according to a method of this application. Refer to FIG. 2 at the same time for ease of understanding. As shown in FIG. 3, in an embodiment of this application, the dry etching device includes: a chamber 110; a base 112, disposed inside the chamber 110, and in principle, disposed at a bottom of the chamber 110; a first electrode 121, disposed on the base 112, a surface of the first electrode 121 including a component-disposing area 123 and an edge area 124 surrounding the component-disposing area 123; a barrier ring 113, disposed in the edge area 124, and located on a periphery of the component-disposing area 123; spacers 114, disposed on an outer side of an electrode plate, and located on a periphery of the barrier ring 113, where the spacer 114 has a plurality of through holes 125; a second electrode 122, disposed inside the chamber 110, and disposed opposite to the first electrode 121; a gas inlet, disposed on an inner side of the chamber 110, where a horizontal position of the gas inlet is higher than a horizontal position of the first electrode 121, the gas inlet is generally disposed at the second electrode 122 at a top of the chamber 110, and is disposed fitting a gas intake apparatus to blow in an etching gas 130, and because the position of the gas inlet overlaps that of the second electrode 122, the gas inlet is not shown in FIG. 3; and a gas extraction opening 141, disposed on an inner side of the chamber 110, and disposed fitting a gas discharge apparatus 142 to discharge the etching gas 130, where a horizontal position of the gas extraction opening 141 is lower than the horizontal position of the first electrode 121, and the gas extraction opening 141 is generally disposed below the base 112 at the bottom of the chamber 110. A constant voltage difference exists between the first electrode 121 and the second electrode 122 and is used to control a flow direction of the etching gas 130.

As shown in FIG. 2 and FIG. 3, the spacer 114 has a plurality of through holes 125. The flow rate, flow direction, and gas distribution uniformity of the etching gas 130 may be restricted according to positions of the through holes 125. In addition, instead of being restricted at corners of the chamber 110, the etching gas 130 may flow through the spacers 114 by way of the through holes 125 to arrive below the spacers, so as to be discharged from the chamber 110 through the gas extraction opening 141.

As shown in FIG. 2, in some embodiments, the spacers 114 are disposed on the periphery of the barrier ring 113 in a manner of no interval (or a continuous arrangement).

As shown in FIG. 2, in some embodiments, the plurality of through holes 125 is evenly provided on the spacer 114.

As shown in FIG. 2, in some embodiments, the plurality of through holes 125 has a same shape and size.

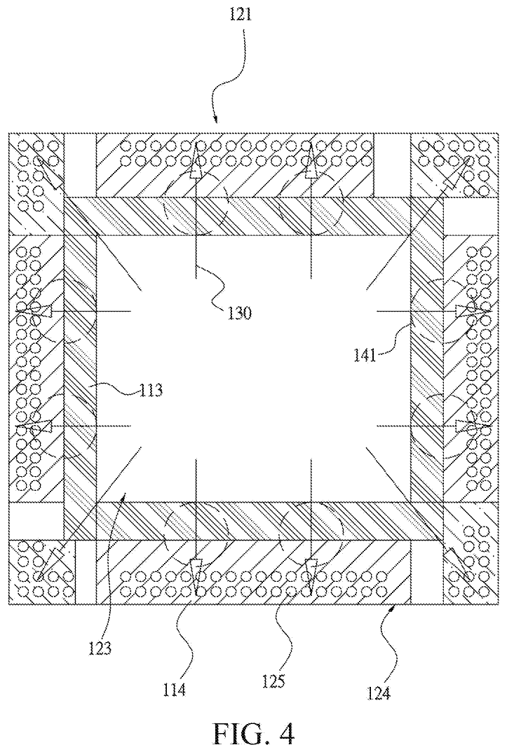

FIG. 4 is a schematic structural top view showing that an embodiment is applied to an electrode of a dry etching device according to a method of this application. In some embodiments, the spacers 114 are disposed on the periphery of the barrier ring 113 in a manner of equal intervals.

In some embodiments, the spacers 114 are disposed on the periphery of the barrier ring 113 in a manner of unequal intervals or partially equal intervals.

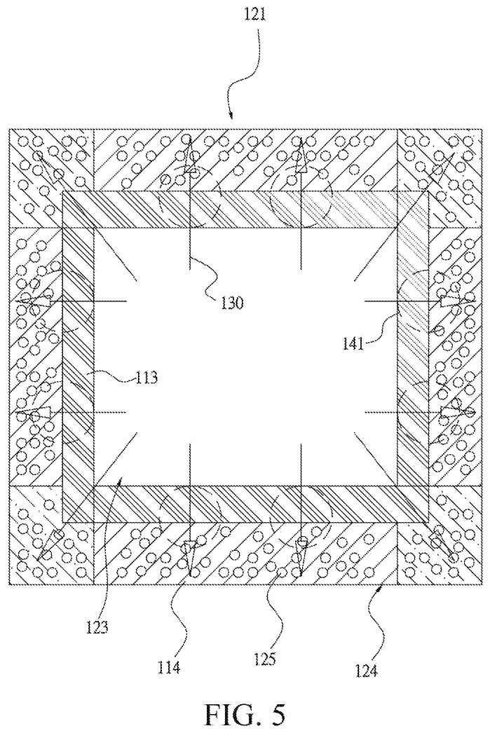

FIG. 5 is a schematic structural top view showing that an embodiment is applied to an electrode of a dry etching device according to a method of this application. In some embodiments, the plurality of through holes 125 is unevenly provided on the spacer 114.

In some embodiments, the plurality of through holes 125 is partially evenly provided on the spacer 114.

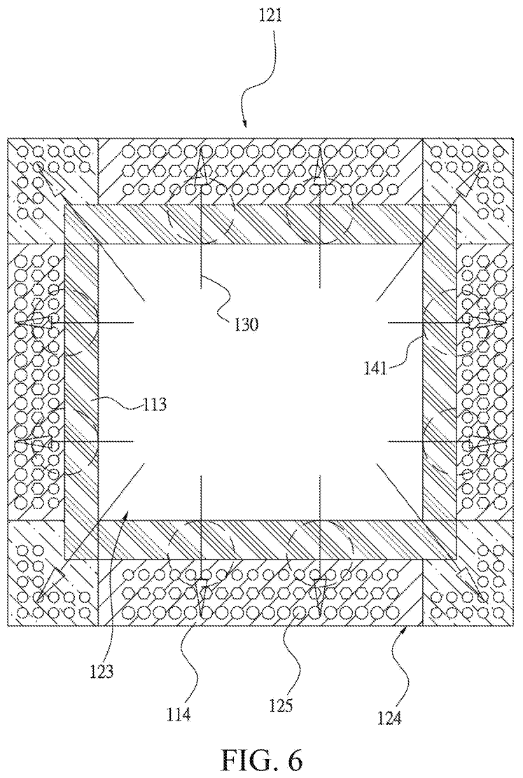

FIG. 6 is a schematic structural top view showing that an embodiment is applied to an electrode of a dry etching device according to a method of this application. In some embodiments, the plurality of through holes 125 has different shapes and sizes or partially same shapes and sizes.

As shown in FIG. 2, in some embodiments, the gas extraction opening 141 is disposed at a bottom of the chamber 110, and is disposed opposite to an opening of the spacer 114.

In some embodiments, the gas extraction opening 141 is disposed on a side of the chamber 110, and abuts the opening 125 of the spacer 114.

By means of this application, distribution uniformity of flow directions of the etching gas 130 can be improved without radically changing an existing dry etching procedure. The etching gas 130 is prevented from constantly flowing to corners inside the chamber 110. Differences between etching degrees of four corners and that of another position of the to-be-processed substrate 200 are reduced. An improper loading effect is reduced. Processing uniformity of parts of the to-be-processed substrate 200 is maintained. The manufacturing yield of the to-be-processed substrate 200 is improved.

In different embodiments, the to-be-processed substrate 200 may be, for example, a glass substrate or a flexible substrate of a display panel. Alternatively, in some embodiments, the to-be-processed substrate 200 may be, for example, a substrate of a semiconductor apparatus.

Terms such as “in some embodiments” and “in various embodiments” are repeatedly used. Usually, the terms do not refer to a same embodiment; but they may also refer to a same embodiment. Words such as “comprise”, “have”, “include” are synonyms, unless other meanings are indicated in the context.

The foregoing descriptions are merely preferred embodiments of this application, and are not intended to limit this application in any form. Although this application has been disclosed above through the preferred embodiments, the embodiments are not intended to limit this application. Any person skilled in the art can make some equivalent variations or modifications according to the foregoing disclosed technical content without departing from the scope of the technical solutions of this application to obtain equivalent embodiments. Any simple amendment, equivalent change or modification made to the foregoing embodiments according to the technical essence of this application without departing from the content of the technical solutions of this application shall fall within the scope of the technical solutions of this application.

What is claimed is:

1. An electrode of a dry etching device, comprising:
an electrode plate, a surface of the electrode plate comprising a component-disposing area and an edge area surrounding the component-disposing area;
a barrier ring, disposed in the edge area, and located on a periphery of the component-disposing area; and
spacers, disposed on an outer side of the electrode plate, and abutting a periphery of the barrier ring, wherein the spacer has a plurality of through holes.

2. The electrode of a dry etching device according to claim 1, wherein the spacers are disposed on the periphery of the barrier ring in a manner of equal intervals, unequal intervals, partially equal intervals or no interval.

3. The electrode of a dry etching device according to claim 1, wherein the plurality of through holes is evenly, unevenly, or partially evenly provided on the spacer.

4. The electrode of a dry etching device according to claim 1, wherein the plurality of through holes has a same shape and size.

5. The electrode of a dry etching device according to claim 1, wherein the plurality of through holes has different shapes and sizes.

6. The electrode of a dry etching device according to claim 1, wherein the plurality of through holes has partially same shapes and sizes.

7. A dry etching apparatus, comprising:
a chamber;
a base, disposed inside the chamber;
a first electrode, disposed on the base, and a surface of the first electrode comprising a component-disposing area and an edge area surrounding the component-disposing area;
a barrier ring, disposed in the edge area, and located on a periphery of the component-disposing area;
spacers, disposed on an outer side of an electrode plate, and abutting a periphery of the barrier ring, wherein the spacer has a plurality of through holes;
a second electrode, disposed inside the chamber, and disposed opposite to the first electrode;
a gas inlet, disposed on an inner side of the chamber, wherein a horizontal position of the gas inlet is higher than a horizontal position of the first electrode; and
a gas extraction opening, disposed on the inner side of the chamber, wherein a horizontal position of the gas extraction opening is lower than the horizontal position of the first electrode.

8. The dry etching device according to claim 7, wherein the spacers are disposed on the periphery of the barrier ring in a manner of equal intervals, unequal intervals, partially equal intervals or no interval.

9. The dry etching device according to claim 7, wherein the plurality of through holes is evenly, unevenly, or partially evenly provided on the spacer.

10. The dry etching device according to claim 7, wherein the plurality of through holes has a same shape and size.

11. The dry etching device according to claim 7, wherein the plurality of through holes has different shapes and sizes.

12. The dry etching device according to claim 7, wherein the plurality of through holes has partially same shapes and sizes.

13. The dry etching device according to claim 7, wherein the gas extraction opening is disposed at a bottom of the chamber, and is disposed opposite to an opening of the spacer.

14. The dry etching device according to claim 7, wherein the gas extraction opening is disposed on a side of the chamber, and abuts an opening of the spacer.

15. A dry etching apparatus, comprising:
a chamber;
a base, disposed inside the chamber;
a first electrode, disposed on the base, a surface of the first electrode comprising a component-disposing area and an edge area surrounding the component-disposing area;
a barrier ring, disposed in the edge area, and located on a periphery of the component-disposing area;
spacers, disposed on an outer side of an electrode plate, and abutting a periphery of the barrier ring, wherein the spacer has a plurality of through holes;
a second electrode, disposed inside the chamber, and disposed opposite to the first electrode;
a gas inlet, disposed on an inner side of the chamber, wherein a horizontal position of the gas inlet is higher than a horizontal position of the first electrode; and
a gas extraction opening, disposed on the inner side of the chamber, wherein a horizontal position of the gas extraction opening is lower than the horizontal position of the first electrode, wherein
the spacers are disposed on the periphery of the barrier ring in a manner of equal intervals, unequal intervals, partially equal intervals or no interval;
the plurality of through holes is evenly, unevenly, or partially evenly provided on the spacer;
the plurality of through holes has a same shape and size, different shapes and sizes, or partially same shapes and sizes; and
the plurality of through holes is used to restrict a flow rate, a flow direction, and gas distribution uniformity of an etching gas.
